(19) United States
(12) Patent Application Publication
(10) Pub. No.: US 2017/0202110 A1
(43) Pub. Date: Jul. 13, 2017

(54) Layered Thermal Spreader

(71) Applicant: CoolChip Technologies, Inc., Somerville, MA (US)

(72) Inventor: Lino A. Gonzalez, Somerville, MA (US)

(21) Appl. No.: 15/406,510

(22) Filed: Jan. 13, 2017

Related U.S. Application Data
(60) Provisional application No. 62/278,120, filed on Jan. 13, 2016.

(51) Int. Cl. H05K 7/20; H01L 23/427; H05K 1/02; F28F 5/00

(52) U.S. Cl. CPC H05K 7/20336; F28F 5/00; H01L 23/427; H05K 1/0203; H05K 7/2039; F28F 2215/14

(57) ABSTRACT

A kinetic heat sink has a stationary member mountable to a heat-generating component, and a rotatable structure coupled with the stationary member across a gap. The stationary member has a heat spreader formed from a plurality of layers that includes a given layer having a radial heat spreading element and an axial heat spreading element. The radial heat spreading element has a first radial thermal conductance. The axial heat spreading element has a second radial thermal conductance. The first radial thermal conductance is greater than the second radial thermal conductance. The axial heat spreading element has a first axial thermal conductance. The radial heat spreading element has a second axial thermal conductance. The first axial thermal conductance is greater than the second effective axial thermal conductance. At least a portion of the axial heat spreading element is radially inward of at least a portion of the radial heat spreading element.

### PRIORITY

This patent application claims priority from provisional U.S. Patent Application No. 62/278,120, filed Jan. 13, 2016, attorney docket number 3769/1016, entitled, “LAYERED THERMAL SPREADER,” and naming Lino Gonzalez as inventor, the disclosure of which is incorporated herein, in its entirety, by reference.

### RELATED PATENT APPLICATIONS

This patent application is related to the following United States patent applications, the disclosures of which each are incorporated herein, in their entireties, by reference.
U.S. patent application Ser. No. 13/911,677, attorney docket number 3769/1006, filed Jun. 6, 2013, entitled, “KINETIC HEAT SINK HAVING CONTROLLABLE THERMAL GAP,” and naming Lino A Gonzalez, William R. Sanchez, and Steven Stoddard as inventors,
U.S. patent application Ser. No. 14/053,848, attorney docket number 3769/1008, filed Oct. 15, 2013, entitled, “KINETIC HEAT SINK WITH SEALED FLUID LOOP,” and naming Lino A Gonzalez, William R. Sanchez, and Steven Stoddard as inventors,
U.S. patent application Ser. No. 14/648,614, attorney docket number 3769/1009, filed May 29, 2015, entitled, “KINETIC HEAT SINK COOLED SERVER,” and naming Lino A Gonzalez, Pramod Chamarthy, Steven Stoddard, William R. Sanchez, and Roger B. Dickinson as inventors,
U.S. patent application Ser. No. 14/784,429, attorney docket number 3769/1011, filed Oct. 14, 2015, entitled, “KINETIC HEAT SINK WITH STATIONARY FINS,” and naming Lino A Gonzalez, Pramod Chamarthy, Florent Nicholas Severac as inventors, and
U.S. patent application Ser. No. 14/601,612, attorney docket number 3769/1014, filed Jan. 21, 2015, entitled, “KINETIC HEAT SINK WITH NON-PARALLEL STATIONARY FINS,” and naming Lino A Gonzalez, Florent Nicholas Severac, Pramod Chamarthy as inventors,

### FIELD OF THE INVENTION

The invention generally relates to heat management devices and, more particularly, the invention relates to kinetic heat sinks for use with electronic components.

### BACKGROUND OF THE INVENTION

During operation, electronic/electric circuits and devices generate waste heat. To operate properly, the temperature of the electronic circuits and devices has to be within a certain limit. The temperature of an electronic device often is regulated using a heat sink physically mounted near or to the electronic device.

One relatively new type of heat management device, known as a “kinetic heat sink,” has a thermal mass with integrated fluid-directing structures (such as fins and/or fan blades) that rotates with respect to a stationary base mounted on or near the electronic device generating the heat. Kinetic heat sinks can provide more efficient cooling in a smaller footprint.

### SUMMARY OF VARIOUS EMBODIMENTS

In accordance with one embodiment of the invention, a kinetic heat sink has a stationary member mountable to a heat-generating component, and a rotatable structure rotatably coupled with the stationary member across a spatial gap. The stationary member has a heat spreader formed from a plurality of layers. In particular, the plurality of layers includes a given layer having a radial heat spreading element and an axial heat spreading element. The radial heat spreading element is oriented and/or configured to have a first effective radial thermal conductance. In a similar manner, the axial heat spreading element is oriented and/or configured to have a second effective radial thermal conductance. The first effective radial thermal conductance is greater than the second effective radial thermal conductance. Furthermore, the axial heat spreading element is oriented and/or configured to have a first effective axial thermal conductance. Additionally, the radial heat spreading element is oriented and/or configured to have a second effective axial thermal conductance. The first effective axial thermal conductance is greater than the second effective axial thermal conductance. At least a portion of the axial heat spreading element is radially inward of at least a portion of the radial heat spreading element.

The axial heat spreading element may form an axial open region. In that case, at least a portion of the radial heat spreading element may be positioned within the axial open region. In a similar manner, the radial heat spreading element may form a radial open region, and at least a portion of the axial heat spreading element may be positioned within the radial open region. In other embodiments, both elements form their respective open regions, and a portion of the other is within that respective region. In some implementations having these open regions, the radial heat spreading element may be considered to be interdigitated with the axial heat spreading element.

The radial heat spreading element may be formed at least in part from a first material, and the axial heat spreading element may be formed at least in part from a second material. The first material preferably is different from the second material. For example, the radial heat spreading element may include a heat pipe. The heat pipe may have a pipe axial thermal resistance, and the axial heat spreading element may include a substantially solid block of material having a block axial thermal resistance. The block axial thermal resistance preferably is less than the pipe axial thermal resistance. In other words, the axial heat spreading element preferably is configured to axially conduct heat better than the radial heat spreading element. In another embodiment, the axial heat spreading element may be a vapor chamber.

The heat spreader further may include an upper layer of a first material and a lower layer of a first material. In that case, the given layer may be positioned between the upper and lower layers. Among other things, the upper and lower layers may include copper. Moreover, the lower layer may be configured to connect with the heat-generating component. A standoff may be coupled between the heat-generating component and one of the layers.

The kinetic heat sink may have a number of other elements. For example, the kinetic heat sink may have a plurality of stationary fins on the stationary member. Moreover, the rotatable structure may include a movable, heat-extraction surface facing the stationary member across the spatial gap.

In accordance with another embodiment of the invention, a kinetic heat sink system includes:

1) a kinetic heat sink having a stationary member and a rotatable structure rotatably coupled with the stationary member across a spatial gap,

2) a heat generating element, and

3) a heat spreader thermally coupled with the stationary member and the heat generating element.

The heat spreader has a stack of a plurality of layers that includes a given layer with a radial heat spreading element and an axial heat spreading element. The radial heat spreading element is oriented and/or configured to have a first effective radial thermal conductance. Additionally, the axial heat spreading element is oriented and/or configured to have a second effective radial thermal conductance. The first effective radial thermal conductance is greater than the second effective radial thermal conductance. Furthermore, the axial heat spreading element is oriented and/or configured to have a first effective axial thermal conductance. Additionally, the radial heat spreading element is oriented and/or configured to have a second effective axial thermal conductance. The first effective axial thermal conductance is greater than the second effective axial thermal conductance. Moreover, the radial heat spreading element has a given radial portion a first distance from the heat generating element, and the axial heat spreading element has a given axial portion a second distance from the heat generating element. The second distance is greater than the first distance.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a cross-sectional view of a kinetic heat sink that may be configured in accordance with illustrative embodiments of the invention.

FIG. 2A schematically illustrates one example of heat dissipation by the kinetic heat sink of FIG. 1.

FIG. 2B shows a bottom perspective view of the kinetic heat sink with alternatively positioned stationary fins in accordance with illustrative embodiments of the invention.

FIG. 3 schematically shows an exploded view of a kinetic heat sink similar to that of FIG. 1 and configured in accordance with illustrative embodiments of the invention.

FIG. 4 schematically shows an exploded view of an alternative embodiment of a kinetic heat sink in accordance with illustrative embodiments of the invention.

FIG. 5 schematically shows an exploded view of a heat spreader that may be used in accordance with illustrative embodiments of the invention.

FIG. 6 schematically shows a top perspective view embodiment of a standoff used with the kinetic heat sink in accordance with illustrative embodiments of the invention.

FIG. 7 schematically shows an exploded view of an alternative embodiment of the heat spreader that may be used in accordance with illustrative embodiments of the invention.

### DESCRIPTION OF ILLUSTRATIVE EMBODIMENTS

In illustrative embodiments, a kinetic heat sink has a base that is specially configured to more efficiently direct heat from a thermally connected heat generating element to its heat dissipating rotating element. To that end, the base has a heat spreader configured to direct thermal energy both axially and radially. The heat spreader thus may be formed with a plurality of layers, where one layer includes both an axial heat spreading element and a radial heat spreading element. Details of illustrative embodiments are discussed below.

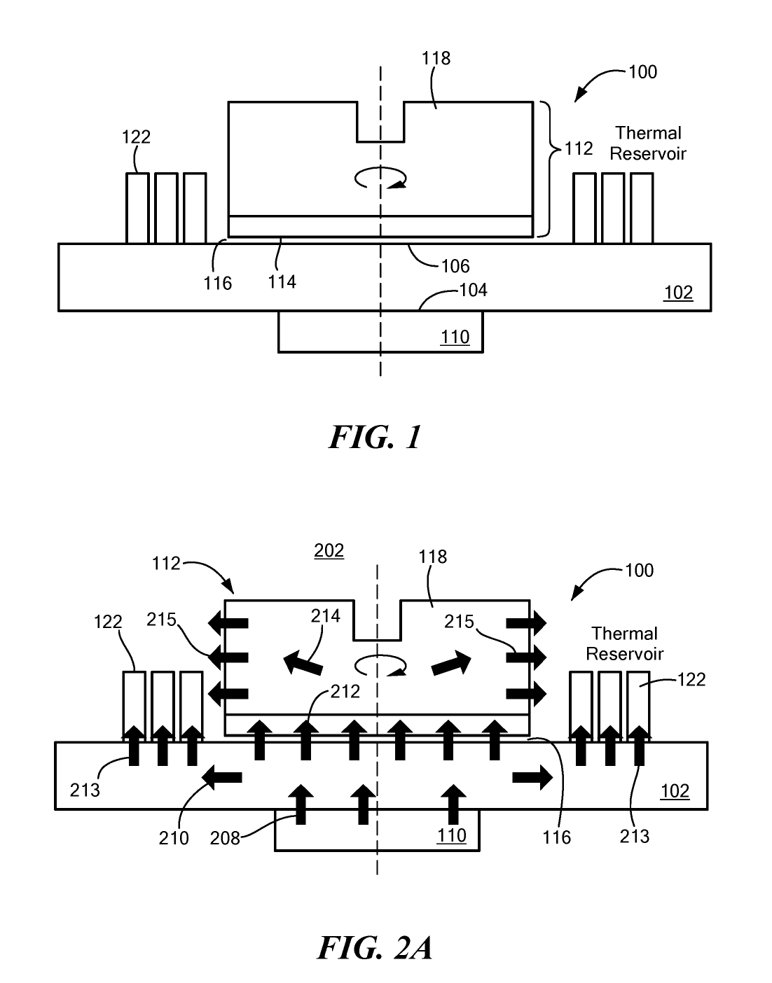

FIG. 1 schematically shows a cross-sectional view of a kinetic heat sink 100 that may be configured according to illustrative embodiments of the invention. The kinetic heat sink 100 has a base structure 102 with both a first heat-conducting surface 104 and a second heat-conducting surface 106 to conduct heat therebetween. The first heat-conducting surface 104 is mountable to a heat-generating component 110, such as an electronic device or component. For example, the heat-generating component 110 may include, among other things, a resistive device, a printed circuit board, or an integrated circuit.

The kinetic heat sink 100 has a rotating structure 112 rotatably coupled with the base structure 102. The rotating structure 112, which may be part of a rotor of an electric motor (not shown), has a movable heat-extraction surface 114 facing the second heat-conducting surface 106 across a fluid gap 116. In some embodiments, when the rotating structure 112 rotates during normal operation, the fluid gap 116 can have a height of between about 10 microns and about 20 microns, having a thermal-resistance characteristic (e.g., less than 0.1 degree Celsius per Watt). Other embodiments form the fluid gap 116 to be larger or smaller.

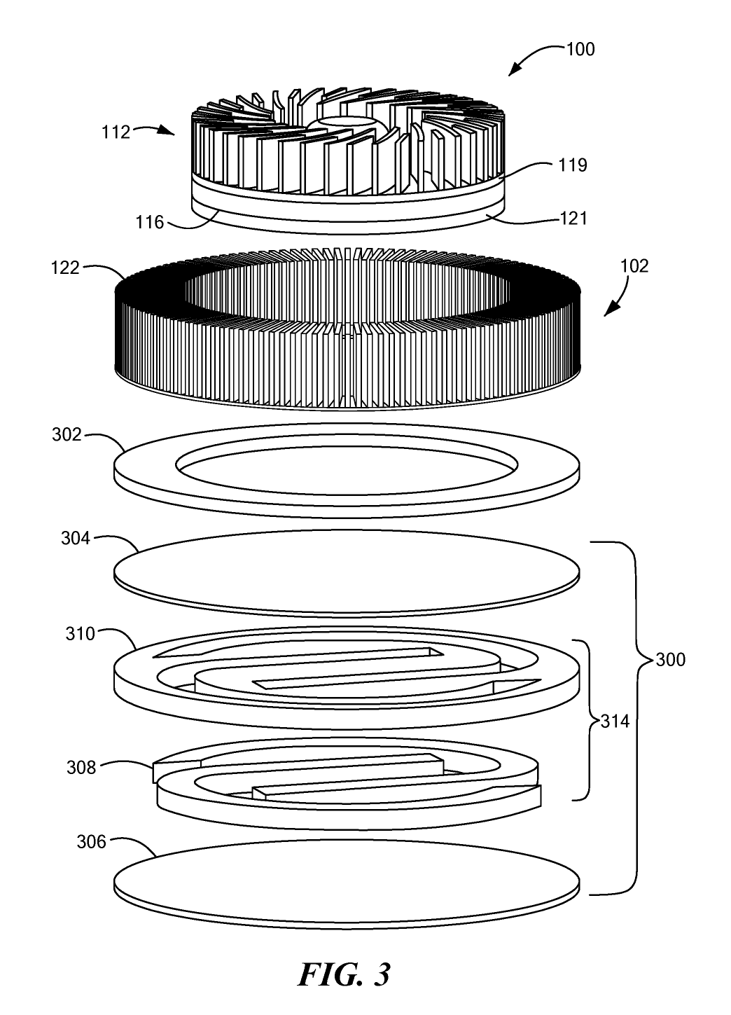

An alternate embodiment forms the fluid gap 116 between vertically concentric fins (not shown) protruding from the rotating and base structures 112, 102. For example, the concentric fins may be on the second heat-conducting surface 106 and may interdigitate with concentric fins on the movable heat-extraction surface 114. In that case, the fluid gap 116 may be about 50 microns or larger. In illustrative embodiments, the thermal resistance across the fluid gap 116 may decrease by more than half during rotation. The rotating structure 112 has rotating fins 118 mounted on a generally flat plate 119 (see FIG. 3). The fins 118 channel thermal energy to a thermal medium (i.e., fluid) when the rotating structure 112 rotates. This thermal energy moves from a region (i.e., first area) of a thermal reservoir communicating with the rotating structure 112 to another area (i.e., second area) of the thermal reservoir. As used herein, the rotating structure 112 may be referred to as an impeller.

The base structure 102 also may have a set of stationary fins 122 extending from the second heat-conducting surface 106 to provide additional heat-dissipating surface areas. The stationary fins 122 are physical structures in the fluid flow path between the first area and the second area of the thermal reservoir. The rotating structure 112 provides the fluid flow to reject heat further from the stationary fins 122. The stationary fins 122, which, as shown, are in the direct path of fluid flow, also reject conducted heat by radiation and natural convection.

The stationary fins 122 may be integral with the second heat-conducting surface 106—effectively part of the base structure 102. Alternatively, the stationary fins 122 may be removably connected with the base structure 102.

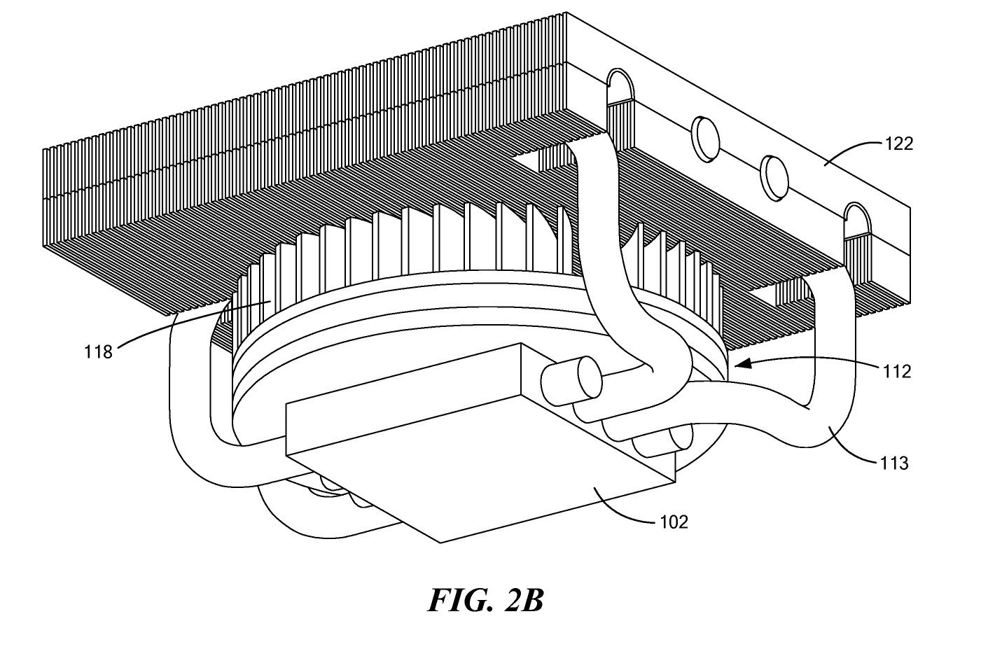

FIG. 2A schematically illustrates an operation of the kinetic heat sink 100 of FIG. 1. In the figure, the rotating structure 112 rotates to channel the thermal medium from a first area 202 of the thermal reservoir to another region (i.e., second area) of the thermal reservoir along a flow path. The fluid-flow may exit the rotating structure 112 in a radial direction. The rotating structure 112 may form a vortex at the first area 202. As fluid flows through the kinetic heat sink 100 (e.g., across the rotating fins 118 of the rotating structure 112), a temperature gradient (i.e., VT) forms between the heat-generating component 110 and the solid volumes of the kinetic heat sink 100. The temperature gradient provides a heat-transfer potential resulting in greater heat extraction between the solid volumes and heat rejection between the solid volume and transfer medium.

Generally, the base structure 102 extracts heat (arrow 208) from the heat-generating component 110 and spreads the heat (arrow 210) across the base structure 102 as discussed below (e.g., see the discussion of a heat spreader). As the heat spreads 210 across the base structure 102, a portion of the heat 212 transfers to the rotating structure 112 across the fluid gap 116, and is rejected into the thermal reservoir by the rotating fins 118. Another portion of the heat 213 spreads through the stationary fins 122 and is rejected into the pre-heated 215 fluid dispelled from the rotating structure 112.

FIG. 2B shows a bottom perspective view of the kinetic heat sink 100 with the stationary fins 122 in an alternative position in accordance with illustrative embodiments of the invention. In this embodiment, the stationary fins 122 may be positioned above the rotating structure 112 (e.g., by mounting the stationary fins 122 on supports 113 that extend from the stationary base 102 to above the rotating fins 118). Thus, in some embodiments, the fluid may be preheated by either the rotating structure 112 or the stationary structure 102.

At low rotation speeds, the thermal-resistance characteristic across the fluid gap 116 is low relative to the thermal resistance of the stationary fins 122. The heat 212 transferred and rejected by the rotating structure 112 may be greater than the heat 213 rejected by the stationary fins 122. As the rotation speed increases, the thermal-resistance characteristics of the stationary fins 122 become lower than the combined resistance of the fluid gap 116 and rotating fins 118. This results in less heat 212 transferred from the base structure 102 to the rotating structure 112 and more of heat 213 spread to the stationary fins 122.

Heat rejection through the rotating structure 112 depends on the thermal resistance of the fluid gap 116 and the thermal resistance of the rotating structure 112. Starting from rest, the thermal resistance of the fluid gap 116 is generally low in relation to the thermal resistance of the rotating structure 112 and the stationary fins 122. At higher speeds, the fluid gap 116 can become a bottleneck in removing heat away from the base structure 102. The stationary fins 122 have no such limitations, however, as they do not require the fluid gap 116, and may therefore operate at higher efficiency (i.e., lower thermal resistance) at higher rotation speeds. Accordingly, stationary fins 122 provide a separate heat transfer and rejection mechanism from the rotating structure 112, which supplements the heat dissipating operation of the rotating structure 112, particularly at higher ranges of rotation speed. It should be noted that although they can improve performance, the stationary fins 122 are optional and thus, not necessary for effective cooling in many applications.

Accordingly, the kinetic heat sink 100 conductively cools the heat-generating component 110 through its base structure 102 and, ultimately, through its rotating structure 112. These elements effectively form a substantially continuous thermally conductive path. The rotating structure 112 then cools itself and the optional stationary fins 122 using convection. This is vastly different from a prior art arrangement using a stationary heat sink with a fan blowing on it. In that noted prior art arrangement, the fan simply convectively cools—it does not conductively cool. Thus, a kinetic heat sink (e.g., the kinetic heat sink 100 of FIG. 1) employs a low-thermally resistive fluid gap 116 (e.g., filled with air) between a rotating heat sink (i.e., the rotating structure 112) and a stationary heat sink structure (i.e., the base structure 102 of FIG. 1).

Although air is generally considered a thermal insulator (i.e., not an efficient thermal transfer medium), when the fluid gap 116 is made sufficiently small (i.e., in the order of tens of micrometers) or other measures are taken, e.g., increasing the heat transfer area in the fluid gap 116, the thermal resistance over the fluid gap 116 may become negligible. Larger gap sizes can suffice, however, in certain circumstances (see some of the incorporated patent applications for examples). The rotating structure 112 therefore conductively draws heat from its stationary base structure 102 through the fluid gap 116.

As suggested above, the thermal reservoir is a space or environment having a relatively large thermal mass compared to the kinetic heat sink 100 and may include a thermal bath, or ambient air in which the kinetic heat sink 100 may sit. The kinetic heat sink 100 may operate in a thermal reservoir having a varying temperature, which may occur, for example, in closed thermal systems.

In accordance with illustrative embodiments of the invention, the base structure 102 is specially configured to direct heat more efficiently from a thermally connected heat conducting element to its heat dissipating rotating structure 112. FIG. 3 schematically shows an exploded view the kinetic heat sink 100 similar to that of FIG. 1. This view shows additional details of the kinetic heat sink 100, including its rotating structure 112 and stationary fins 122.

Although plate 121 is shown in this figure apparently as part of the rotating structure 112, it should be understood the plate 121 is part of the stationary base 102 (i.e., it does not rotate). For example, the plate 121 is fixedly coupled to the top plate 304 via thermal interface material (e.g., thermal grease). Thus, the second heat conducting surface 106 is on the plate 121, and forms the fluid gap 116 with the movable heat-extraction surface 114.

In addition, this view also shows a heat spreader 300 configured to improve thermal performance of the entire kinetic heat sink 100. This view also shows an optional spacer element 302 that can support the stationary fins 122. The optional spacer element 302 preferably is formed from a thermally conductive material (e.g., aluminum or copper) to enhance thermal conduction from the heat spreader 300 to the stationary fins 122.

In this embodiment, the heat spreader 300 includes a plurality of layers that together both axially and radially cooperate to more effectively direct thermal energy upwardly/axially (from the perspective of the drawing) from the heat-generating component 110. Those layers include a thermally conductive top sheet 304 to provide a substantially flat surface for mounting the stationary fins 122, and a corresponding thermally conductive bottom sheet 306 to provide a substantially flat surface for mounting to the heat-generating component 110 (not shown in FIG. 3). In illustrative embodiments, the top and bottom sheets 304 and 306 are formed from a metal, such as copper.

Accordingly, the top and bottom sheets 304 and 306 should have a sufficient thermal conductivity in both the axial direction (i.e., in a direction generally parallel with the central axis of the rotating structure 112), and in the radial direction (i.e., in a direction substantially normal to the axis of the rotating structure 112). Other embodiments may use plates that are not substantially flat, or configured in another manner. The top and bottom sheets 304 and 306 cooperate with an interior layer 314 to axially and radially dissipate heat (discussed below).

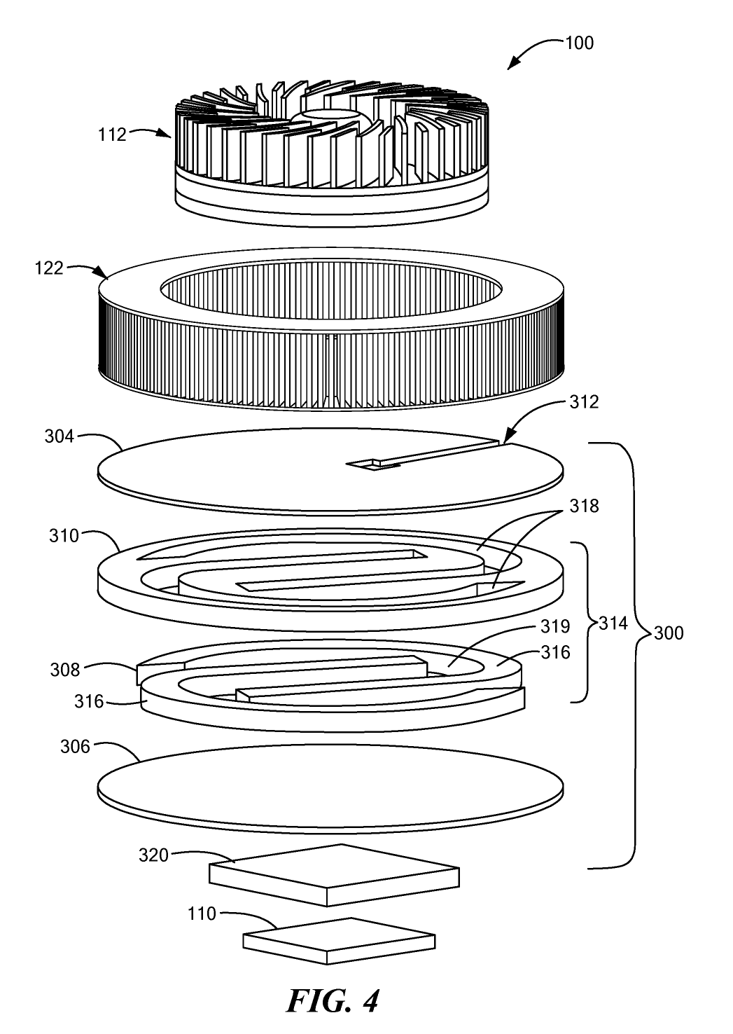

FIG. 4 schematically shows an exploded view of an alternative embodiment of the kinetic heat sink 100 similar to that of FIG. 1, in accordance with illustrative embodiments of the invention. The top and bottom sheets 304 and 306 axially cover the noted interior layer 314 having a plurality of different components. In some embodiments, the top and/or bottom sheets 304 and 306 may have a passage 312 for wires from the kinetic heat sink 100.

The interior layer 314 includes one or more radial heat spreading elements 308 that complimentarily nest and/or interlock with one or more axial heat spreading elements 310. The radial heat spreading elements 308 preferably provide better thermal conduction in the radial direction than they do in the axial direction. In a corresponding manner, the axial heat spreading elements 310 provide equal or better thermal conduction in the axial direction than they do in the radial direction.

The heat spreader 300 preferably is a generally planar structure. The layer 314 of the heat spreader 300 similarly preferably is a generally planar structure. As such, the radial heat spreading element 308 and the axial heat spreading element 310 respectively also may be referred to as in-plane heat spreading element 308 and through-plane heat spreading element 310.

To that end, illustrative embodiments of the radial heat spreading element 308 includes one or more heat pipes 316 configured to spread heat radially. As known by those skilled in the art, heat pipes 316 typically have a conductive outer shell that forms an interior reservoir for a phase-changing coolant. Heat pipes 316 conduct heat well along their length. Thus, illustrative embodiments shape the heat pipes 316 to conduct heat radially outward (e.g., from a central position on the kinetic heat sink 100). To reduce the profile of the device and ensure secure layering, the heat pipes 316 preferably have flat top and bottom sides. Although shown as having flat sides, the heat pipes 316 may have rounded side surfaces.

In contrast, the axial heat spreading element 310 preferably includes one or more single pieces of material having a high thermal conductivity. For example, the axial heat spreading element 310 may be formed as a single piece of an aluminum or copper extrusion. In some other embodiments, the axial heat spreading element 310 may include a vapor chamber. As shown in the example of FIG. 4, the axial heat spreading element 310 is in the form of a single component having an outer rim and an axial open region 318. The outer rim forms the edge of the heat spreading element 310.

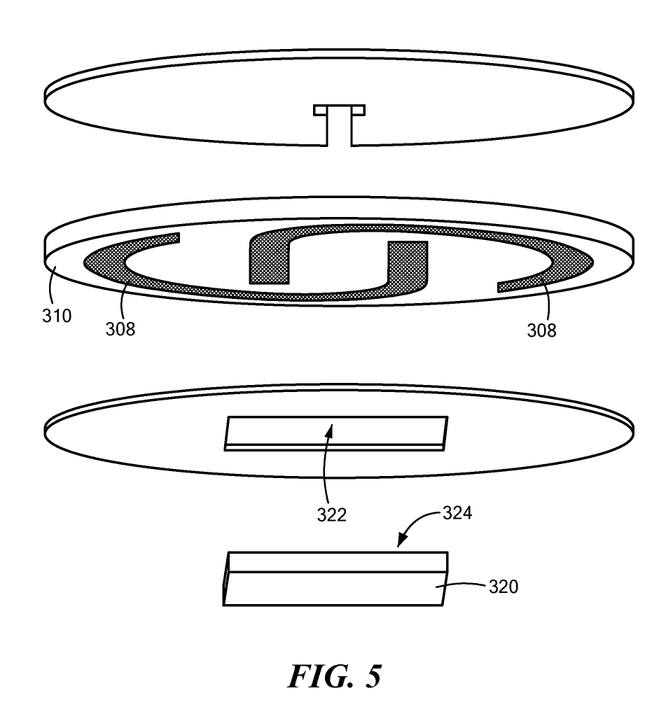

As discussed above, in illustrative embodiments, the axial head spreading element 310 is an aluminum extrusion (i.e., a solid piece of material), and the radial heat spreading element 308 is a heat pipe 316. However, this is merely exemplary, and not all embodiments of the invention are intended to be limited by the above example. Generally, the radial heat spreading element 308 is oriented and/or configured to have a higher effective heat conductance in a radial direction than the axial heat spreading element 310. In a similar manner, the axial heat spreading element 310 is oriented and/or configured to have a higher effective heat conductance in an axial direction than the radial heat spreading element 308. For example, the heat pipe 316 conducts heat well along its length. Thus, the length of the heat pipe 316 may be shaped as a “U” that extends radially outward, as shown in FIG. 5. In such a configuration, the heat pipe 316 conducts heat well in a direction that is generally radially outward.

As known by those in the art, an effective thermal conductance is a single number that represents the thermal conductance of a single element (e.g., one of the radial or axial heat spreading elements 308 and 310). That single number may be used as a specification for the element, and for thermal modeling. Commonly, the effective thermal conductance is a number derived from the combination of various components of a multi-component element. For example, the effective thermal conductance of the radial heat spreading element 308 is a function of both the heat pipe and the coolant fluid in the heat pipe. In a similar manner, if formed from a single material, such as aluminum, the axial heat spreading element 310 has an effective thermal conductance based on the single material—the aluminum. Thus, the latter case is the trivial solution to the effective thermal conductance since it has only a single component.

In various embodiments and as known by those in the art, radially inward and outward thermal conductance are with respect to the outer periphery of heat spreader 300 and/or the kinetic heat sink 100. For example, in the embodiment shown in FIG. 3, radial thermal conductance or position is inside the round outer perimeter defined by the heat spreader 300. In a corresponding manner, the axial direction is considered to extend generally in the same direction as (e.g., parallel) the axis of the overall kinetic heat sink 100. In the example of FIG. 3, the axial direction extends in a direction that is generally parallel with the axis of the rotating member 112 (i.e., through the thickness of the heat spreader 300).

To ensure that they both share a single layer, the radial heat spreading element 308 and axial heat spreading element 310 may have complementary shapes that effectively nest together to form a single layer—they are coplanar. This complimentary shaping may cause the two elements 308 and 310 to interlock and/or fit in registry with each other. In illustrative embodiments, at least a portion of the axial heat spreading element 310 is radially inward of at least a portion of the radial heat spreading element 308 when assembled. To that end, the axial heat spreading element 310 forms the axial open region 318, while the radial heat spreading element 308 correspondingly forms a radial open region 319.

The radial heat spreading element 308 fits within the axial open region 318. In a like manner, the axial heat spreading element 310 fits within the radial open region 319. Thus, the radial heat spreading element 308 and the axial heat spread element 310 are coplanar. For example, the axial open region 318 may match the shape of the heat pipes 316. An interference fit may be formed by the heat pipes 316 and the axial open region 318. However, in some embodiments there is a clearance between the sidewalls of the heat pipe 316 and the axial open region 318. In illustrative embodiments, solder paste may fill the clearance and also be used to hold the axial heat spreading element 310 and the radial heat spreading element 308 together. The axial heat spreading element 310 and radial heat spreading element 308 thus together effectively conduct heat both axially and radially in a single layer to improve performance of the overall kinetic heat sink 100.

Illustrative embodiments may also have a standoff 320 that prevents/mitigates the risk that the kinetic heat sink 100 contacts underlying electrical components. For example, the kinetic heat sink 100 may be mounted to a computer processor (e.g., heat-generating component 110) that itself is mounted on a motherboard. The standoff 320 provides additional clearance between the kinetic heat sink 100 and the motherboard. The standoff 320 may be formed from, for example, copper or aluminum to conduct heat from the heat-generating component 110 to the kinetic heat sink 100.

The standoff 320 may be a unitary piece with the bottom sheet 306. For example, the bottom sheet 306 and the standoff 320 may be machined as a single piece. Alternatively, the standoff 320 may be manufactured separately and attached to the bottom sheet 306, for example, by applying solder paste between the two pieces, 320 and 306, and heating (e.g., baking). Application of excessive solder paste between the two pieces, 320 and 306, may cause leakage that creates an undesirable visual appearance. Alternatively, too little solder paste may not spread evenly between the two surfaces. Areas that do not have solder paste may have air between them, which increases thermal resistance (i.e., contact thermal resistance) between the standoff and the bottom sheet. To that end, illustrative embodiments may have a slot configured to accept the standoff 320.

FIG. 5 schematically shows an exploded view of an alternative embodiment of the kinetic heat sink 100 with the slot 322 that accepts the standoff 320. Solder paste is applied to the top surface 324 of the standoff 320, and the standoff 320 is inserted into the slot 322 until it contacts the axial heat spreading element 310 and/or the radial heat spreading element 308. Thus, the standoff 320 may be soldered directly to the axial heat spreading element 310 and/or the radial heat spreading element 308. As discussed above, although the axial heat spreading element 310 and the radial heat spreading element 308 are shown as having an interference fit, this is not intended to limit various embodiments of the invention. There may be some clearance between the axial heat spreading element 310 and the radial heat spreading element 308. In illustrative embodiments, solder paste may be in the clearance.

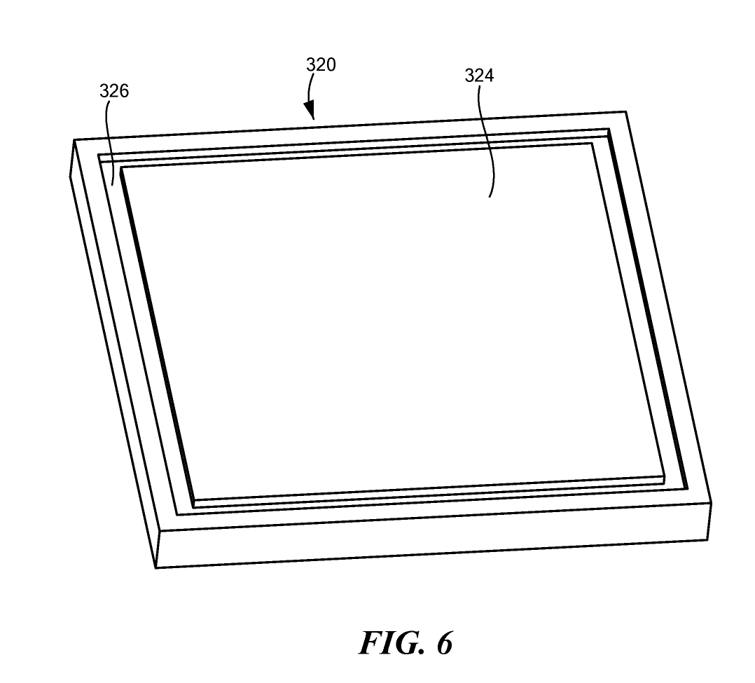

FIG. 6 schematically shows a top perspective view of an alternative embodiment of the standoff 320 in accordance with illustrative embodiments of the invention. As described above, solder paste is applied to the top surface 324 of the standoff 320, and the standoff 320 is soldered against a surface (e.g., bottom sheet 306, radial heat spreading element 308 and/or axial heat spreading element 310). Too much solder paste, or unevenly applied solder paste, may cause leakage. As shown, the standoff 320 may have a channel 326 that collects excess solder paste circumscribing the outer perimeter. Thus, the channel 326 may prevent excess solder paste from leaking out.

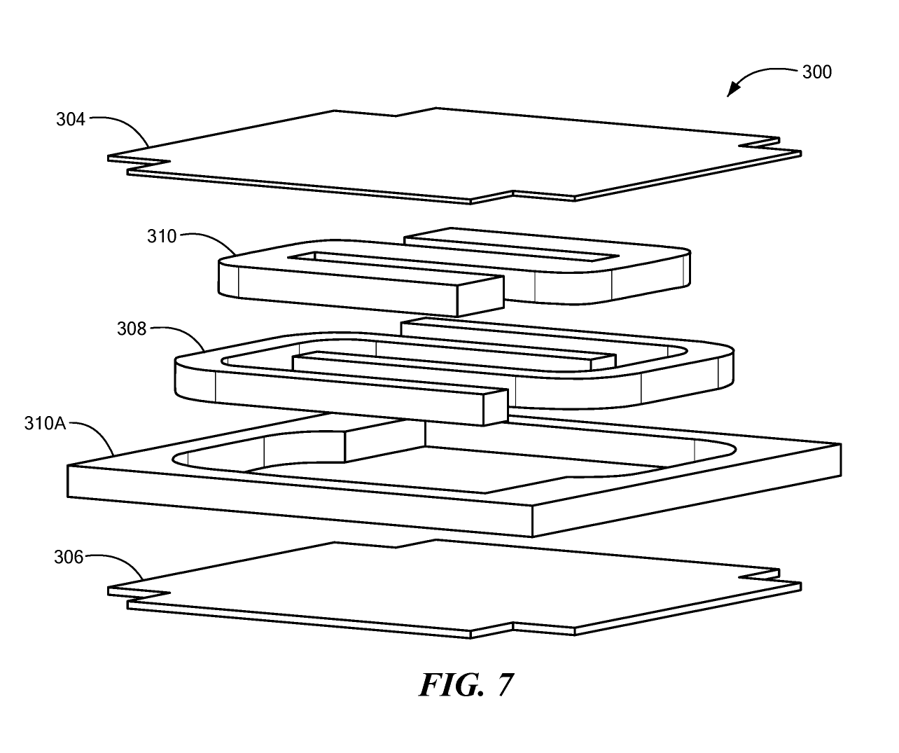

FIG. 7 schematically shows another embodiment of the heat spreader 300. Unlike the embodiments of FIGS. 3 and 4, the heat spreader 300 of this embodiment has a substantially rectangular overall shape. In addition, this embodiment has a discontinuous axial heat spreading element 310. Specifically, the axial heat spreading element 310 of this embodiment uses an outer frame 310A, which also adds support and overall stiffness, and an interior portion. In some embodiments, both of these elements are formed from similar, or the same, material, such as aluminum. Thus, they may be considered to be part of the same component. If, however, the outer frame 310A is not substantially thermally conductive, then the frame may not be considered to be part of the axial heat spreading element 310.

The heat spreader 300 may be a separate element from the overall kinetic heat sink 100. In other words, the kinetic heat sink 100 may have a bottom surface that secures to the heat spreader 300. Accordingly, in some embodiments, the kinetic heat sink 100 still may work satisfactorily without the heat spreader 300, although the heat spreader 300 may improve performance when added to the kinetic heat sink 100.

Because the kinetic heat sink 100 may be used in small spaces, the heat spreader 300 preferably has a thin profile relative to the height of overall kinetic heat sink 100. In other words, the heat spreader 300 preferably does not add a significant amount of height to the overall kinetic heat sink 100. For example, the heat spreader 300 may make up less than about 20 percent of the total height of the kinetic heat sink 100. As yet a further example, a prototype of the heat spreader 300 is between about 5 millimeters and 6 millimeters thick (e.g., 5.5 millimeters).

In alternative embodiments, the heat spreader 300 may have multiple layers that each includes both an axial heat spreading element 310 and a radial heat spreading element 308. In yet other embodiments, the heat spreader 300 may have the arrangement of FIG. 4, but with one or more other layers with only axial heat spreading element 310 or a radial heat spreading element 308.

Accordingly, in illustrative embodiments, the heat spreader 300, which may integrate with the kinetic heat sink 100, uses two specially configured, different structures in a single layer to more efficiently direct heat from a thermally connected heat-generating component 110 to its heat dissipating rotating element 112.

Although the above discussion discloses various exemplary embodiments of the invention, it should be apparent that those skilled in the art can make various modifications that will achieve some of the advantages of the invention without departing from the true scope of the invention.

What is claimed is:

1. A kinetic heat sink comprising:
a stationary member mountable to a heat-generating component, the stationary member comprising a heat spreader;
a rotatable structure rotatably coupled with the stationary member across a spatial gap to form the kinetic heat sink,
the heat spreader coupled with the stationary member, the heat spreader including a plurality of layers, the plurality of layers including a given layer having a radial heat spreading element and an axial heat spreading element,
the radial heat spreading element oriented and/or configured to have a first effective radial thermal conductance, the axial heat spreading element oriented and/or configured to have a second effective radial thermal conductance, the first effective radial thermal conductance being greater than the second effective radial thermal conductance,
the axial heat spreading element oriented and/or configured to have a first effective axial thermal conductance, the radial heat spreading element oriented and/or configured to have a second effective axial thermal conductance, the first effective axial thermal conductance being greater than the second effective axial thermal conductance, and
at least a portion of the axial heat spreading element being radially inward of at least a portion of the radial heat spreading element.

2. The kinetic heat sink as defined by claim 1 wherein the axial heat spreading element forms an axial open region, at least a portion of the radial heat spreading element being within the axial open region.

3. The kinetic heat sink as defined by claim 1 wherein the radial heat spreading element forms a radial open region, at least a portion of the axial heat spreading element being within the radial open region.

4. The kinetic heat sink as defined by claim 1 wherein the axial heat spreading element forms an axial open region, the radial heat spreading element forming a radial open region,
at least a portion of the radial heat spreading element being within the axial open region,
at least a portion of the axial heat spreading element being within the radial open region.

5. The kinetic heat sink as defined by claim 1 wherein the radial heat spreading element is formed at least in part from a first material, the axial heat spreading element being formed at least in part from a second material, the first material being different from the second material.

6. The kinetic heat sink as defined by claim 1 wherein the radial heat spreading element comprises a heat pipe.

7. The kinetic heat sink as defined by claim 1 wherein the axial heat spread element comprises a vapor chamber.

8. The kinetic heat sink as defined by claim 1, wherein the radial heat spreading element comprises a heat pipe having a pipe axial thermal resistance, the axial heat spreading element comprising a substantially solid block of material having a block axial thermal resistance, the block axial thermal resistance being less than the pipe axial thermal resistance.

9. The kinetic heat sink as defined by claim 1 wherein the heat spreader further includes an upper layer of a first material and a lower layer of the first material, the given layer being between the upper and lower layers.

10. The kinetic heat sink as defined by claim 9 wherein the lower layer is configured to connect with the heat-generating component.

11. The kinetic heat sink as defined by claim 1 wherein the given layer is generally planar.

12. The kinetic heat sink as defined by claim 1 further comprising a plurality of stationary fins on the stationary member.

13. The kinetic heat sink as defined by claim 1 wherein the rotatable structure comprises a movable, heat-extraction surface facing the stationary member across the spatial gap.

14. The kinetic heat sink as defined by claim 1 wherein the radial heat spreading element is interdigitated with the axial heat spreading element.

15. The kinetic heat sink as defined by claim 1 further comprising a standoff coupled to the kinetic heat sink.

16. A kinetic heat sink system comprising:
a kinetic heat sink having a stationary member, and a rotatable structure rotatably coupled with the stationary member across a spatial gap;
a heat generating element; and
a heat spreader thermally coupled with the stationary member and the heat generating element, the heat spreader having a stack of a plurality of layers, the plurality of layers including a given layer having a radial heat spreading element and an axial heat spreading element,
the radial heat spreading element oriented and/or configured to have a first effective radial thermal conductance, the axial heat spreading element oriented and/or configured to have a second effective radial thermal conductance, the first effective radial thermal conductance being greater than the second effective radial thermal conductance,
the axial heat spreading element oriented and/or configured to have a first effective axial thermal conductance, the radial heat spreading element oriented and/or configured to have a second effective axial thermal conductance, the first effective axial thermal conductance being greater than the second effective axial thermal conductance,
the radial heat spreading element having a given radial portion a first distance from the heat generating element, the axial heat spreading element having a given axial portion a second distance from the heat generating element, the second distance being greater than the first distance.

17. The kinetic heat sink system as defined by claim 16 wherein the heat spreader is mechanically coupled to the stationary member.

18. The kinetic heat sink system as defined by claim 16 wherein the axial heat spreading element forms an axial open region, at least a portion of the radial heat spreading element being within the axial open region.

19. The kinetic heat sink system as defined by claim 16 wherein the radial heat spreading element forms a radial open region, at least a portion of the axial heat spreading element being within the radial open region.

20. The kinetic heat sink system as defined by claim 16 wherein the radial heat spreading element includes a heat pipe and the axial heat spreading element comprises a single, unitary element.

21. A kinetic heat sink comprising:
a stationary member mountable to a heat-generating component, the stationary member comprising means for spreading heat;
a rotatable structure rotatably coupled with the stationary member across a spatial gap to form the kinetic heat sink,
the heat spreading means coupled with the stationary member, the heat spreading means including a plurality of layers, the plurality of layers including a given layer having a radial heat spreading means and an axial heat spreading means,
the radial heat spreading means oriented and/or configured to have a first effective radial thermal conductance, the axial heat spreading means oriented and/or configured to have a second effective radial thermal conductance, the first effective radial thermal conductance being greater than the second effective radial thermal conductance,
the axial heat spreading means oriented and/or configured to have a first effective axial thermal conductance, the radial heat spreading means oriented and/or configured to have a second effective axial thermal conductance, the first effective axial thermal conductance being greater than the second effective axial thermal conductance, and
at least a portion of the axial heat spreading means being radially inward of at least a portion of the radial heat spreading means.

22. The kinetic heat sink as defined by claim 21, wherein:
the radial heat spreading means comprises a heat pipe shaped to conduct heat radially outward, and
the axial heat spreading means comprises a block of solid material.

23. The kinetic heat sink as defined by claim 21, wherein the stationary fins are positioned axially above the rotating structure.

24. The kinetic heat sink as defined by claim 21 wherein the heat spreading means further includes an upper layer and a lower layer comprising copper, the given layer being between the upper and lower layers.
